(19) United States
(12) Patent Application Publication
(10) Pub. No.: US 2026/0030413 A1
(43) Pub. Date: Jan. 29, 2026

(54) SYSTEM AND METHODS FOR DETERMINING DATA FROM BUILDING DRAWINGS

(71) Applicant: Onboard Data, Inc., Somerville, MA (US)

(72) Inventors: Brian Spencer Simmons, Somerville, MA (US); Edward Jackson Alexander, Somerville, MA (US)

(73) Assignee: Onboard Data, Inc., Somerville, MA (US)

(21) Appl. No.: 18/998,963

(22) PCT Filed: Jul. 27, 2023
(86) PCT No.: PCT/US2023/028837

§ 371 Date: Jan. 27, 2025

Related U.S. Application Data
(60) Provisional application No. 63/392,997, filed on Jul. 28, 2022.

(51) Int. Cl. G06F 30/27; G06V 30/41

(52) U.S. Cl. CPC G06F 30/27; G06V 30/41

(57) ABSTRACT

Techniques for determining equipment names and other information from engineering drawings are described. In an example embodiment, image data representing at least a portion of an engineering drawing for a building is received, the image data is processed using a first ML model to identify a first portion of the image data corresponding to a first region from a set of regions, the first portion of the image data is processed to recognize first text data, using at least a second ML model the first text data is determined to correspond to a first equipment type from a set of equipment types, wherein the set of equipment types relate to the equipment included in the building, and using the first equipment type and an ontology representing relationships between equipment types and equipment name, a first equipment name corresponding to the first text data is determined.

### FEDERALLY SPONSORED RESEARCH

The present invention was made with U.S. government support under Award No. DE-SC0019958, awarded by the Department of Energy (DOE) SBIR Phase II. The U.S. government has certain rights in the invention.

### FIELD

Aspects of the technology described herein relate to analyzing data, obtained from building engineering drawings and other related drawings, for building automation and control systems.

### BACKGROUND

Building automation and control systems include systems that monitor, control and record functions of different building systems (e.g., heating, ventilation, and cooling systems, electricity, lighting, etc.). As part of automating and controlling these building systems, other devices or components including sensors, alarms, and setpoints may be associated with equipment used in operating these building systems. These devices or components may provide data used in controlling these building systems as well as information relating to performance of certain pieces of equipment (e.g., fans, air handling units, boiler, chiller, etc.).

### SUMMARY

Some embodiments are directed to a computer-implemented method, the method comprising receiving image data representing at least a portion of an engineering drawing for a building, the building including equipment; processing, using a first machine learning (ML) model, the image data to identify a first portion of the image data corresponding to a first region from a set of regions, wherein each region in the set of regions relates to a type of information included in the engineering drawing; processing the first portion of the image data to recognize first text data; determining, using at least a second ML model, that the first text data corresponds to a first equipment type from a set of equipment types, wherein the set of equipment types relate to the equipment included in the building, wherein the second ML model is configured to classify text as corresponding to one of the set of equipment types; determining, using the first equipment type and an ontology representing relationships between equipment types and equipment name, a first equipment name corresponding to the first text data; and presenting, via a user interface, first data indicative of the first equipment name along with a representation of the first portion of the image data and the first text data.

A system comprising at least one processor; and at least one non-transitory computer-readable storage medium storing processor-executable instructions that, when executed by the at least one processor, cause the at least one processor to: receive image data representing at least a portion of an engineering drawing for a building, the building including equipment; process, using a first machine learning (ML) model, the image data to identify a first portion of the image data corresponding to a first region from a set of regions, wherein each region in the set of regions relates to a type of information included in the engineering drawing; process the first portion of the image data to recognize first text data; determine, using at least a second ML model, that the first text data corresponds to a first equipment type from a set of equipment types, wherein the set of equipment types relate to the equipment included in the building, wherein the second ML model is configured to classify text as corresponding to one of the set of equipment types; determine, using the first equipment type and an ontology representing relationships between equipment types and equipment name, a first equipment name corresponding to the first text data; and present, via a user interface, first data indicative of the first equipment name along with a representation of the first portion of the image data and the first text data.

At least one non-transitory computer-readable storage medium storing processor-executable instructions that, when executed by at least one processor, cause the at least one processor to: receive image data representing at least a portion of an engineering drawing for a building, the building including equipment; process, using a first machine learning (ML) model, the image data to identify a first portion of the image data corresponding to a first region from a set of regions, wherein each region in the set of regions relates to a type of information included in the engineering drawing; process the first portion of the image data to recognize first text data; determine, using at least a second ML model, that the first text data corresponds to a first equipment type from a set of equipment types, wherein the set of equipment types relate to the equipment included in the building, wherein the second ML model is configured to classify text as corresponding to one of the set of equipment types; determine, using the first equipment type and an ontology representing relationships between equipment types and equipment name, a first equipment name corresponding to the first text data; and present, via a user interface, first data indicative of the first equipment name along with a representation of the first portion of the image data and the first text data.

### BRIEF DESCRIPTION OF DRAWINGS

Various aspects and embodiments will be described with reference to the following figures. The figures are not necessarily drawn to scale.

FIG. 1 is a conceptual diagram of a system for obtaining data from building engineering drawings, according to embodiments of the present disclosure.

FIG. 2 shows an example building engineering drawing that may be processed using the system of FIG. 1.

FIG. 3 shows example components of an image processing component of the system, according to embodiments of the present disclosure.

FIG. 4A shows example components of a text recognition component of the system, according to embodiments of the present disclosure.

FIG. 4B shows an example image corresponding to a diagrams region with text recognition boxes.

FIG. 4C shows example text bounding boxes and transcribed text.

FIG. 5 shows example components of a text classification component of the system, according to embodiments of the present disclosure.

FIG. 6A shows further components of the system that can be used to provide building data for various tasks, according to embodiments of the present disclosure.

FIG. 6B shows a graph illustrating iterative steps taken in updating a model, according to embodiments of the present disclosure.

FIG. 7 is a conceptual diagram illustrating some example equipment included in a building.

FIG. 8 is a conceptual diagram illustrating further components of the system, according to embodiments of the present disclosure.

FIG. 9 is a block diagram of an illustrative computer system that may be used in implementing some embodiments of the technology described herein.

### DETAILED DESCRIPTION

Aspects of the present application relate to techniques for extracting data from building engineering drawings and analyzing the extracted data for building automation and control systems. The data extracted from the building engineering drawings may correspond to equipment, devices, and other systems in a building, such as mechanical systems, security systems, fire systems, flood safety systems, lighting systems, heating systems, ventilation systems, and air conditioning (HVAC), humidity control systems, elevators, etc. The techniques described herein may be applied to various types of buildings, including residential buildings, commercial buildings, and industrial buildings. The equipment, devices and other systems may be collectively referred to as “building systems” herein. The extracted data may be analyzed to determine which of the building systems the data corresponds to, and may be used in facilitating building automation and control systems or performing other analysis with respect to the building (e.g., energy usage assessment, location mapping of building systems, etc.).

Building automation and control systems and other building analysis may use various measurement points (referred to herein as “points”) associated with building systems. Examples of point types include sensors, actuators, setpoints, alarms, and the like. Examples of types of building systems include air handling units, variable-air-volume boxes, boilers, chillers, fans, filters, thermostats and the like. A single piece of equipment may be associated with many points, including different types of points. For example, a variable-air-volume box may be associated with several points, including an air flow sensor, a temperature sensor, and a setpoint. Techniques described herein may be used to identify which points correspond to the data extracted from the building engineering drawings. A setpoint refers to the point/condition at which a building system is set to activate or deactivate. For example, a heating system may be set to switch on if the internal temperature falls below 20° C., an extract fan might be set to switch on if the relative humidity in a room exceeds 65%, etc.

Aspects of the present application involve processing image data representing a building engineering drawing. Examples of building engineering drawings include building control drawings, sequence of operations text, floor plans with HVAC duct layout, mechanical sections, mechanical details, mechanical flow diagrams, network diagrams, equipment schedules, notes, legends, and the like. Building engineering drawings may include information in various forms, such as text, tables, diagrams, floor plans, etc. Moreover, building engineering drawings are generally flat providing two-dimensional information about a three-dimensional building environment. Building engineering drawings also do not have distinctive foreground and background, which are typically useful in automated image processing. As such, extracting information from building engineering drawings can be challenging.

Some embodiments of the present disclosure involve processing the image data to divide the image into portions or regions based on the type of information represented in the respective region. Such processing may involve use of object recognition techniques and/or image segmentation techniques. For example, a first portion of the image may include a table and may be associated with a “table region”, and a second portion of the image may include a diagram and may be associated with a “diagram region.” In example embodiments, a system may identify the following regions: information box, notes, diagram, table, floor plan, and duct work plan.

Some embodiments of the present disclosure further involve recognizing text from the determined portions/regions of the image. Such processing may involve use of text recognition techniques. In some embodiments, a different text recognition technique or machine learning model may be used to extract text from different regions of the image. For example, a first technique may be used to recognize text from tables, and a second technique may be used to recognize text from diagrams.

Some embodiments of the present disclosure further involve determining a building system and/or a point corresponding to the recognized text. Such processing may involve use of machine learning classification techniques. The recognized text may be classified, on a line-by-line basis, into equipment types or instances, and/or point types. Some implementations involve identifying labels for individual text lines or instances. An example of a label is a point type label, which identifies the type of measurement point (e.g., temperature measurements, air flow measurements, setpoint values, etc.). Another example of a label is an equipment type label, which identifies the type of equipment (e.g., air handling units, variable-air-volume boxes, boilers, chillers, etc.). A further example of a label is an equipment instance label, which identifies the equipment instance the text corresponds to such as ‘VAV 001’. Yet a further example of a label is location, which identifies the location of the equipment or point within a building. Other types of labels may also be used and embodiments are not limited in this respect.

Techniques of the present disclosure relate to use of computer vision and other techniques for extracting information from floor plans for real-estate and information extraction from building engineering diagrams. Moreover, the techniques of the present disclosure also relate to solving information fusion problems related to the extracted information.

It should be appreciated that the various aspects and embodiments described herein be used individually, all together, or in any combination of two or more, as the technology described herein is not limited in this respect.

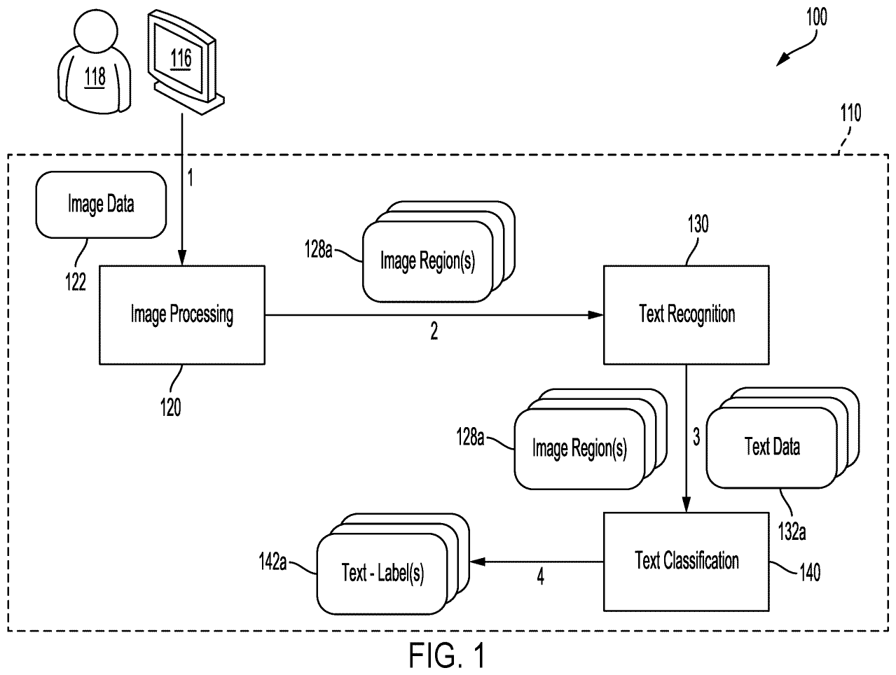

FIG. 1 is a conceptual diagram of a system 100 for extracting data by processing image data representing building engineering drawings. In example embodiments, the system 100 may include an image processing component 120, a text recognition component 130 and a text classification component 140, which may be collectively referred to as system/device 110. The foregoing components may be implemented at a computing device(s) (e.g., a single computing device, multiple computing device(s) co-located in a single physical location or located in multiple physical locations remote from one another, one or more computing devices part of a cloud computing system, etc.). In other embodiments, the system 100 may include fewer or more components than shown in FIG. 1. Although the figures and discussion of the present disclosure illustrate certain steps in a particular order, the steps described may be performed in a different order (as well as certain steps removed or added) without departing from the present disclosure.

The system 100 may be a neural-network based deep learning architecture that automates data preprocessing, feature extraction, and classification. In some embodiments, the system 100 may jointly learn multiple tasks, which can lead to improved performance compared to learning the tasks individually.

The system 100 may be configured to implement (and test) one or more computer vision techniques and optical character recognition (OCR) techniques for extracting data building engineering drawings, which may be structured drawings, unstructured drawings or semi- structured drawings. The system 100 may be used to extract data from various sources that are used to manually label building data. Such sources may include Equipment Control Drawings, Equipment Sequence of Operations, and Floor Plans with HVAC Duct Layout. Data may be extracted from other sources as well. As part of training operations, various drawings from the foregoing sources may be annotated with ground truth labels. By incorporating these data sources, the system 100 can be configured as an automated classification system that can learn from all the same sources a human/building engineer expert uses. Additionally, the data sources may facilitate capture of metadata such as motor-horsepower, equipment's physical location, and areas of the building being served.

Some aspects of the system 100 may involve extracting parcel boundaries and identifiers linked to ownership information, which may be similar to the goal of segmenting and extracting labels such as ‘VAV 001’ from duct layout plans and associated tables.

In addition to reducing errors by information fusion, another reason to process data from multiple sources is the measurement uncertainty arising from differences between design drawings and what was actually built on site. Many building systems may be repaired, replaced or otherwise modified over time as needs change, and such modifications may be reflected in different drawing sources.

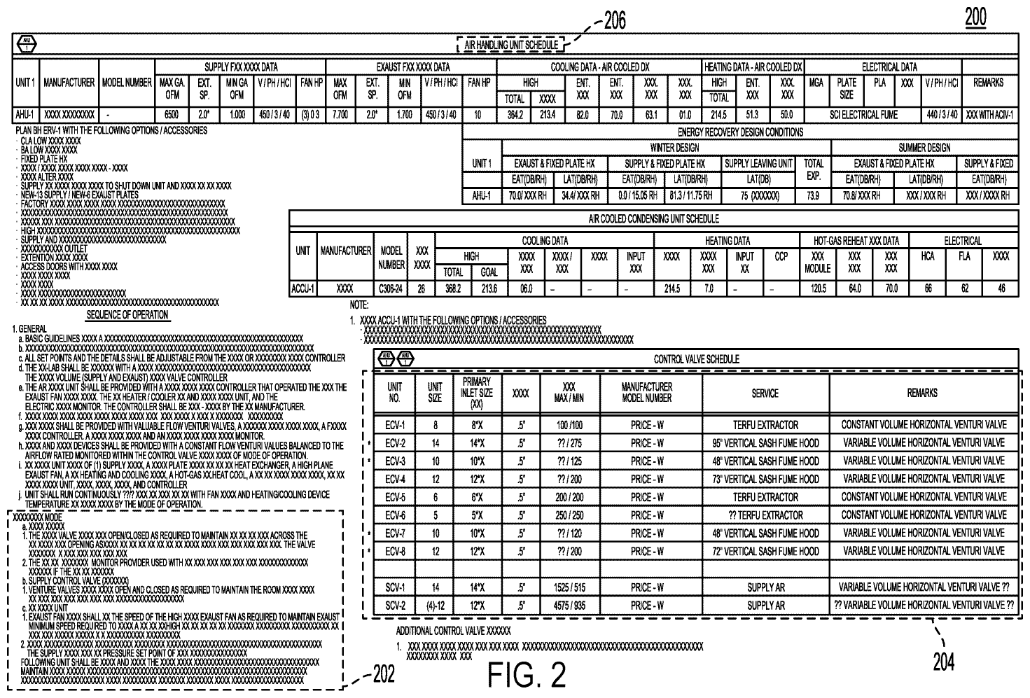

The system 100 may include a computing device 116 being operated by a user 118. The system 100 may process image data 122, which may include one or more images representative of a building engineering drawing or a portion thereof. The computing device 116 may send (step 1) the image data 122 to an image processing component 120. The user 118 may be a developer or an engineer that is configuring the system 100 for various tasks. The user 118 may be an end-user who wants actionable building data for a building represented in the provided building engineering drawings/image data 122. Below is a description of example building engineering drawings that may be processed by the system 100. FIG. 2 shows an example of a portion of an HVAC layout drawing 200, which may be processed by the system 100.

Equipment Control Drawings describe the wiring details of sensors, actuators, and their physical locations within the unit. The information from these drawings may contribute to the following classification tasks: (1) labeling Vs, e.g., labeling HX-1 as a Heat Exchanger; (2) extracting lists of point types, e.g., “Hot Water Return Temperature”, “Mixing-Valve”; and (3) grouping the list of point types into specific equipment instance cluster.

Equipment Sequence of Operations are sheets included in an HVAC engineering drawing that describe how specific types of equipment, like Air Handlers, will perform across many modes such as normal operations, emergency operations or safety shutdowns. Since these sheets contain mostly connected prose, they are most responsive to transcription using OCR models and information extraction using language modeling and sequence labeling approaches from Natural Language Processing (NLP) methods. The sequence of operations contains information pertaining to the list of equipment classes in a building, a list of specific equipment instances in sequence (e.g. ACF-4, ACF-5, ACF-6, etc.), and list of point classes (e.g., Chilled Water Valve, Mixed Air Temperature Sensor, etc.) found in these equipment instances.

Floor plans with HVAC Duct Layout may be the least structured type of engineering drawing that the system 100 may process. These drawings contain information regarding the equipment relation label. Equipment Relationship labels map the functional relationships between an air handling unit (AHU), which initially conditions air that is fed downstream to variable-air volume boxes (VAVs), where it is tempered to meet terminal zone conditions. Ground truth data (for configuring models) may contain positional information of related equipment instances. Using the relative positions of equipment instances in drawings, such as Floor Plans with HVAC Duct Layout, the system of the present disclosure can generate a set of probable equipment relationships.

The system 100 may process various file formats of the image data 122, such as PDFs, JPEGs, etc. In some embodiments, the image data 122 may be a single page of a building engineering drawing. In other embodiments, the image data 122 may be multiple pages of a building engineering drawing. The system 100 may process individual pages at a time or in parallel.

The building engineering drawing may include information related to a set of label types of interest: point types, equipment types, equipment instances, equipment relationship and equipment location. The system 100 may process the image data 122 to extract data related to at least these four label types. The system 100 may extract data for other label types. In some embodiments, the system 100 may output structured data, for example a data table, that indicates observations of the equipment and sensors in a building.

To obtain data from the image data 122, the system 100 may be configured to perform three tasks: (1) segmentation of a drawing into distinct regions; (2) recognition of symbols and text in each region; and (3) inference and mapping of information into a common schema or model that generalizes across various buildings.

The image processing component 120 may be configured to perform the segmentation task, where the image processing component 120 may process the image data 122 and may automatically identify a region, from among a set of regions, that corresponds to a portion of the image data 122. In some embodiments, the image processing component 120 may be configured to identify the following regions: Information box (which include information, such as drawing title, building name, date, etc. related to the drawing and/or building), Tables, Connected Text, HVAC layout, Floor plans without HVAC layout, Scale (a legend box that represents the ratio between the drawing dimensions and its real-life dimensions) and Diagrams. Portions of the image data 122 that do not correspond to any of the other regions may be identified as diagrams region. Table regions and diagram regions can be used to extract equipment types, and connections between equipment instances and points. Floor plan regions and scale regions help determine the dimensions and layout of buildings' floors. HVAC layout regions provide information about location of different pieces of equipment and how they are physically connected.

The drawing 200 of FIG. 2 includes markups (using dashed rectangles) for illustrating certain regions that can be identified by the image processing component 120. The markup 202 corresponds to a Connected Text region. The markup 204 corresponds to a Tables region. The markup 206 corresponds to an Information Box region.

The image processing component 120 may output one or more image regions 128. An image region 128 may correspond to a portion of the image data 122, and may include pixels (e.g., x,y coordinates) representing the portion of the image data 122. The image region 128 may also be associated with or may include a region identifier (e.g., text label, numerical identifier, etc.) identifying the region, from the set of regions, that correspond to the image region 128. For example, first image region 128a may include first pixel data, from the image data 122, and a first region identifier for the information box region. As a further example, second image region 128b may include second pixel data, from the image data 122, and a second region identifier for the scale region.

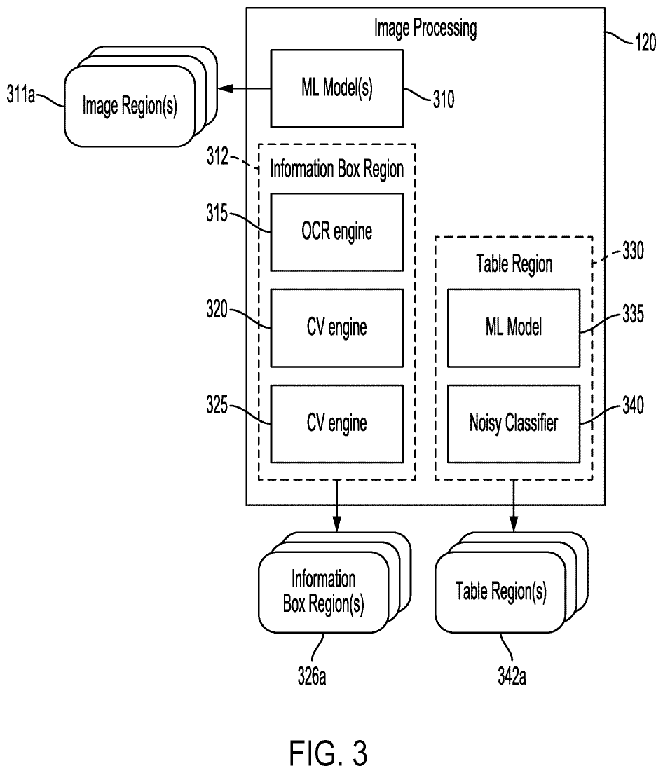

FIG. 3 shows example components of the image processing component 120. The image processing component 120 may employ one or more machine learning (ML) models 310 configured to identify image regions 311 corresponding to portions of the image data 122. The ML model(s) 310 may implement one or more computer vision techniques. The ML model(s) 310 may be configured to identify bounding boxes within the image data 122, where each bounding box may include a portion of the image data 122 and may correspond to an individual image region 311. The ML model(s) 310 may further identify which region, from the set of regions (e.g., Information box region, Tables region, Connected Text region, HVAC layout region, Floor plans without HVAC layout region, Scale region, and Diagrams region), the image region 311 corresponds to. For example, the ML model(s) 310 may identify a first bounding box surrounding a table represented in the image data 122 and identify the first bounding box as corresponding to the tables region. As a further example, the ML model(s) 310 may identify a second bounding box surrounding a wiring diagram represented in the image data 122 and identify the second bounding box as corresponding to the diagrams region. In some embodiments, individual bounding boxes may include non-overlapping portions of the image data 122. In other embodiments, individual bounding boxes may include overlapping portions of the image data 122.

Building engineering drawings may include tables in various forms. In some cases, tables included in the building engineering drawings may not have clear boundaries, may be connected with other tables, and/or may overlap with other tables and other information included in the drawing. Also in some cases, wiring diagrams with crossing vertical and horizontal lines may appear to be tables. This can make it challenging to identify portions of a drawing that correspond to the tables region. The ML model(s) 310 may be trained using sample building engineering drawings that are annotated with the various regions that the image processing component 120 is configured to identify.

In some embodiments, the image processing component 120 may employ three techniques for identifying the information box region. The processing of the three techniques is shown in an information box region component 312 in FIG. 3, which may output one or more information box regions 326 representing portions of the image data 122 that correspond to the information box region from the set of regions.

One of the techniques may involve use of an OCR engine 315 or model to compute the frequency of words. During training operations, the OCR engine 315 may treat words that appear in more than 80% (or another percent) of the training images as title-block text, and may use the bounding box from those words to infer the information box region in the drawing.

Another technique may involve use of a computer vision (CV) engine 320 (e.g., OpenCV tools) to extract contour boxes in the image. The CV engine 320 may be configured to cluster the contour boxes using a data clustering technique (e.g., a density-based spatial clustering of applications with noise (DBSCAN) technique) according to the coordinates of the contour boxes. If a cluster contains contour boxes from more than 60% (or another percent) of the training images then this cluster may be identified as corresponding to the information box region. In order to generate the final segmentation of the image data, the image processing component 120 may merge all the contour boxes in each cluster, and may merge all clusters corresponding to the information box region to define the segmentation box coordinates.

Another technique may involve use of a CV engine 325 (e.g., OpenCV tools) to detect common areas within a drawing. The CV engine 325 may be configured to detect common areas across all the pages of each training image file, then sort the detected contents into common areas by counting the number of common pixels and use the “and” operation among all the common areas to infer the final template for each image file. The CV engine 325 may be configured based on the observation that many image files (e.g., PDF) are generated from computer-aided design (CAD) software. Most CAD software packages utilize a common template and certain information boxes tend to appear in the same location on the page. The information box region component 312 may combine the outputs generated by the three techniques, the OCR engine 315, the CV engine 320 and the CV engine 325, using a ‘majority voting system’ which selects the region of the drawing to segment as the information box region 326.

In some embodiments, the image processing component 120 may employ two techniques for identifying one or more table regions 342, which are shown in a table region component 330 of FIG. 3. The table region 342 may include a portion of the image data 122 corresponding to the table region from the set of regions.

One technique may involve use of a ML model 335, for example, a deep learning model, which may be a Regions with Convolutional Neural Network (R-CNN) based object detection method. The ML model 335 may be trained on the task of detecting tables from various papers. In particular, the ML model 335 may use a deep CNN network to extract vision features of tables and may predict potential significant regions in the images. The ML model 335 may also use the features of each region to classify the region as a table or non-table by minimizing the difference between the predicted region and the ground truth region. The ML model 335 can improve the precision of detecting table regions because it was capable of identifying diverse table shapes, tables with borders, and tables without borders.

Another technique may involve use of a noisy classifier 340 that can discriminate between table and non-table regions in engineering drawings. The noisy classifier 340 may transform drawing images into features that can be used in a clustering algorithm. As one example, noisy classifier 340 may employ an image hash library, which utilizes cryptographic hashing algorithms to transform images into a hash value such that similar images generate similar hashes, and exact matches are used for image fingerprinting.

As another example, noisy classifier 340 may be based on a pre-trained deep residual neural network for image classification (e.g., ResNet-50), which may capture multiple complicated vision features due to its deep convolutional neural network architecture. In some embodiments, the feature results output from the pre-trained residual neural network may be fed into a k-Means clustering algorithm. In some embodiments, k may be 50. The cluster results may be categorized into three bins, where one bin includes clusters containing tables, a second bin includes clusters containing non-tables, and a third bin includes clusters containing some portion of a table. The noisy classifier 340 may be developed by adding another output layer and nodes to the existing ResNet-50 architecture, and re-trained with the binned/labeled cluster results.

In other embodiments, the image processing component 120 may use one machine learning model or technique to identify the regions corresponding to portions of the image data 122. In other embodiments, the image processing component 120 may include other techniques specifically configured to identify portions of images that correspond to other types of regions.

In some embodiments, the image processing component 120 may process the image data 122 using the ML model(s) 310, the information box region component 312 and the table region component 330, and may then perform processing to select between or combine overlapping regions. For example, the ML model(s) 310 may identify a first image region 311a corresponding to a table region and including a first portion of the image data 122, and the table region component 330 may identify a first table region 342a including a second portion of the image data 122, where the first portion of the image data 122 may overlap (e.g., have some or all pixels in common) with the second portion of the image data 122. In such example cases, the image processing component 120 may select the image region 311a or the table region 342a to output as the image region 128 (shown in FIG. 1), where the selection may be based on the portion size (e.g., select the larger portion of the image data 122), confidence value of the component identifying the region (e.g., select the one with a higher confidence value), and/or other factors. Alternatively, the image processing component 120 may include both of the first image region 311a and the table region 342a in the image regions 128.

Referring to FIG. 1, the image processing component 120 may send (step 2) the image regions 128 to the text recognition component 130. The text recognition component 130 may be configured to recognize text within the individual identified image regions 128 of the image data 122. In some embodiments, the text recognition component 130 may employ different text recognition techniques based on the region. Each of the region types may have different structures and spatial organization of text (e.g., table data in individual cells, or diagrams with text spread diffusely across the page), and the text recognition component 130 may use a different text recognition technique that is better suited for the region type.

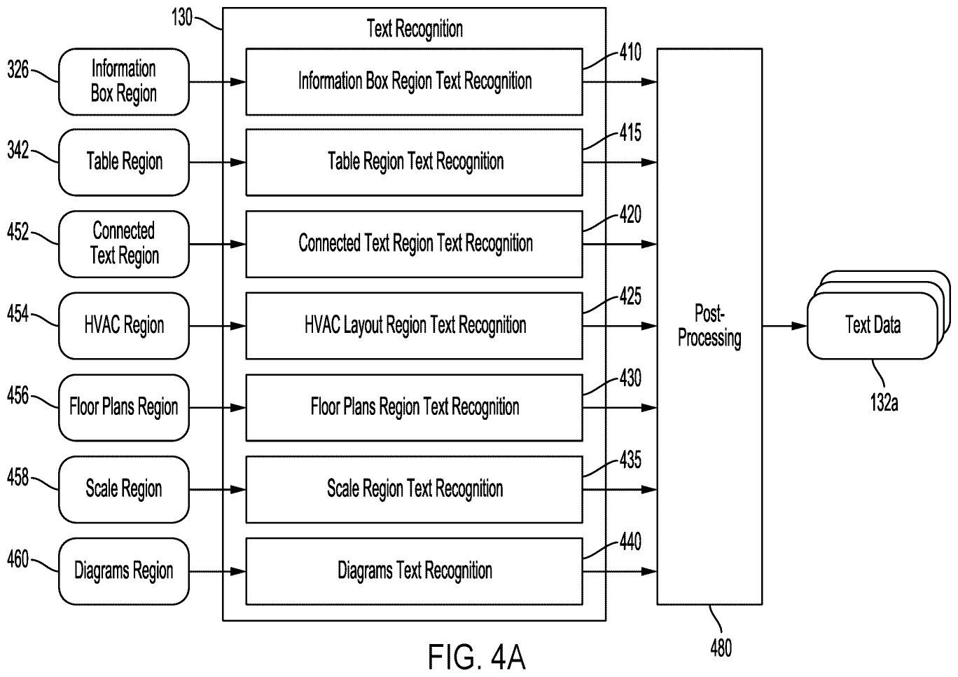

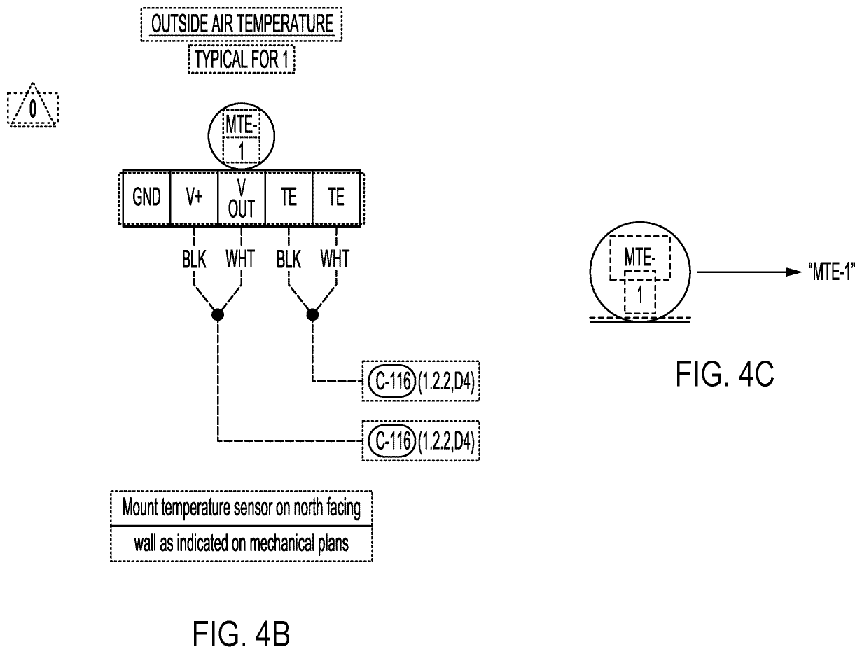

In some embodiments, as part of recognizing text, the text recognition component 130 may perform two tasks—one of text detection/segmentation and the other of text transcription. The text detection/segmentation task may involve detecting portions of the image region 128 that represents text, and may involve generating bounding boxes around portions that represent text. The bounding boxes may be generated to include groups of words that correspond to one another. For example, a bounding box may be generated to include a line of text, such as a sentence. The text detection/segmentation task may also generate bounding boxes for text that appears in a vertical orientation, a diagonal orientation, a horizontal orientation, etc. Moreover, the text detection/segmentation task is also capable of distinguishing text from other graphics that may be included in an engineering drawing and could be mistaken for text, such as, as lines representing wiring, circles representing sensors, etc. Example bounding boxes are shown as dashed rectangles in FIG. 4B.

The text transcription task may involve deriving text data from the bounding boxes, which may also be referred to as transcribing text from an image, recognizing text from an image, etc. The text transcription task may analyze individual bounding boxes, determined by the text detection/segmentation task, to determine text data represented in the individual bounding box. The text transcription task may be capable of recognizing groups of corresponding words, either based on the words included in a bounding box and/or based on performing additional processing. For example, the text transcription task may group bounding boxes based on overlap between the boxes, proximity of the bounding boxes, etc. As a further example, the text transcription task may use learned language modeling (e.g., related to building engineering vocabulary, natural language grammar rules, etc.) to determine that words/bounding boxes correspond to one another. FIG. 4C shows example bounding boxes, one surrounding “MTE-” and another surrounding “1”. The text transcription task may generate the text “MTE—1” from the two bounding boxes.

The text recognition component 130 may employ a ML model(s) to perform the text detection/segmentation task, and may employ another ML model(s) to perform the text transcription task. In some embodiments, the text recognition component 130 may not perform the separate foregoing tasks, but rather employ a component(s) and/or ML model(s) capable of directly transcribing text from an image.

In some embodiments, the text recognition component 130 may include multiple separate components, where individual components may be configured to process a particular image region corresponding to a particular region type. FIG. 4A shows such example components of the text recognition component 130. As shown in FIG. 4A, the text recognition component 130 may include an information box region text recognition component 410 that may be configured to determine text data (which may be included in the text data 132 outputted by the text recognition component 130) from the information box region 326 (described in relation to FIG. 3). The information box region text recognition component 410 may be configured/trained using image data that corresponds to the information box region type. The information box region text recognition component 410 may employ one or more ML models, one or more OCR techniques, and/or other techniques.

A tables region text recognition component 415 that may be configured to determine text data (which may be included in the text data 132 outputted by the text recognition component 130) from the table region 342 (described in relation to FIG. 3). The table region text recognition component 415 may be configured/trained using image data that corresponds to the table region type. The table region text recognition component 415 may employ one or more ML models, one or more OCR techniques, and/or other techniques.

A connected text region text recognition component 420 that may be configured to determine text data (which may be included in the text data 132 outputted by the text recognition component 130) from connected text region 452, which may be included in the image regions 128 outputted by the image processing component 120. The connected text region text recognition component 420 may be configured/trained using image data that corresponds to the connected text region type. The connected text region text recognition component 420 may employ one or more ML models, one or more OCR techniques, and/or other techniques.

A HVAC layout region text recognition component 425 that may be configured to determine text data (which may be included in the text data 132 outputted by the text recognition component 130) from HVAC region 454, which may be included in the image regions 128 outputted by the image processing component 120. The HVAC region text recognition component 425 may be configured/trained using image data that corresponds to the HVAC layout region type. The HVAC region text recognition component 425 may employ one or more ML models, one or more OCR techniques, and/or other techniques.

A floor plans region text recognition component 430 may be configured to determine text data (which may be included in the text data 132 outputted by the text recognition component 130) from floor plans region 456, which may be included in the image regions 128 outputted by the image processing component 120. The floor plans region text recognition component 430 may be configured/trained using image data that corresponds to the floor plans region type. The floors plan region text recognition component 430 may employ one or more ML models, one or more OCR techniques, and/or other techniques.

A scale region text recognition component 435 may be configured to determine text data (which may be included in the text data 132 outputted by the text recognition component 130) from scale region 458, which may be included in the image regions 128 outputted by the image processing component 120. The scale region text recognition component 435 may be configured/trained using image data that corresponds to the scale region type. The scale region text recognition component 435 may employ one or more ML models, one or more OCR techniques, and/or other techniques.

A diagrams region text recognition component 440 may be configured to determine text data (which may be included in the text data 132 outputted by the text recognition component 130) from diagrams region 460, which may be included in the image regions 128 outputted by the image processing component 120. The diagrams region text recognition component 440 may be configured/trained using image data that corresponds to the diagrams region type. The diagrams region text recognition component 440 may employ one or more ML models, one or more OCR techniques, and/or other techniques.

The individual text data 132 may include or be associated with a corresponding confidence value that may be generated by the respective text recognition components 410, 415, 420, 425, 430, 435, 440.

Prior to determining the text data 132, in some embodiments, the individual text/outputs of the components 410, 415, 420, 425, 430, 440 may be processed using a post-processing component 480. The post-processing component 480 may be configured to perform OCR post-processing, which may involve processing text across various drawings types and determining corrections, updates, etc. to the text/outputs of the text recognition components. The post-processing component 480 may implement one or more multi-input attention methods to fuse information from Equipment Sequence of Operations, Floor Plans, and other sources.

FIG. 4B shows an example image corresponding to a diagrams region, that may be processed to recognize text within the diagrams region. Dashed rectangles in FIG. 4B show the text that may be identified by the text recognition component 130.

With regards to text recognition techniques, the system 100 may involve the following subtasks: (1) exploiting mechanical equipment schedules to train more accurate baseline models; (2) implementing multi-input attention methods to fuse information from Equipment Sequence of Operations, Floor Plans, and other sources; and (3) retraining different text recognition (e.g., OCR) models using unsupervised adaptation techniques.

Referring to FIG. 1, the text recognition component 130 may send (step 3) the text data 132 to the text classification component 140. In some embodiments, the image regions 128 may also be provided (e.g., by the text recognition component 130 or another component of the system 110) to the text classification component 140. In some embodiments, individual text data 132 may be associated with individual image regions 128 to identify which text data is derived from which image region.

The text classification component 140 may be configured to identify one or more labels, from among a set of labels, corresponding to individual text data 132. In an example embodiment, the set of labels may include a point type label, an equipment type label, an equipment instance label, location, and an equipment relationship label. The text classification component 140 may involve the tasks of labeling the point type and equipment type, which is to generate two labels for each sensor point. For example, what the sensor is measuring (point type) and what the sensor is connected to (equipment type). In computer vision, the task of grouping pixels together and labeling them as part of the same instance of an object (e.g., person, car, or tree) is known as ‘instance segmentation.’ Similarly, the task of grouping sensor points together into specific equipment instances, such as ‘AHU-1’, can be described as an instance segmentation task.

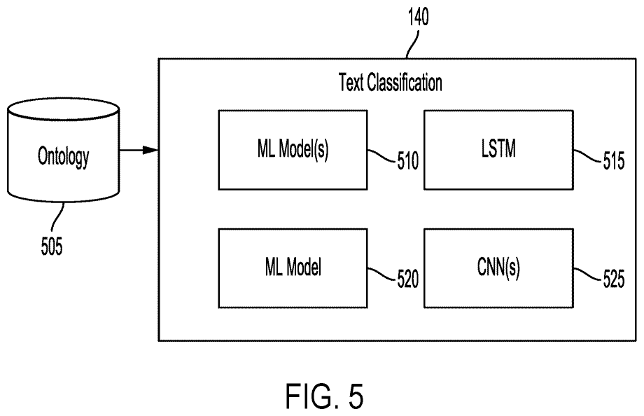

FIG. 5 shows example components of the text classification component 140. The text classification component 140 may receive the text data 132, augmented with the associated images regions 128, and may determine the label (whether the text corresponds to a point type, an equipment type, an equipment instance, or location). An equipment instance label may be determined based on the text representing an identifier, such as an alphanumerical value, associated with an equipment name. For example, in the text “10-011 VAV”, the text “10-011” may be determined to correspond to an equipment instance label, whereas the text “VAV” may be determined to correspond to an equipment type label. As another example, the text “place sensor on north facing wall” may be determined to correspond to a location label. Additionally, the text classification component 140 may determine that the (first) text representing an equipment instance corresponds to the (second) text representing a location. This mapping between equipment instance label and location is determined using the relative positions of the two texts in diagram regions 128, and using the relationships between the two texts in parsed mechanical schedules (tables). Information from the equipment instance label itself may additionally be used to influence these mappings (e.g., the equipment instance with the label “VAV-201” is more likely to exist on the second floor of a building). The text classification component 140 may further determine a tag (or other data), from an ontology 505, that corresponds to the text data 132.

The text classification component 140 may further determine a tag (or other data), from an ontology 505, that corresponds to the text data 132. In some embodiments, the ontology 505 may include data representing classes of equipment types (AHU, VAV, etc.), classes of point types (Discharge Air Temperature Sensor, Outdoor Air Flow, etc.), types of Equipment Relationships, (parent/child) and equipment location. The ontology 505 may include data (e.g., tags) representing (additional) attributes associated with an equipment class/type, which may be beneficial in further defining an equipment instance identified from the image data 122. For example, the ontology 505 may include a first tag “direct expansion cooling” or “dxCool” associated with an air handling unit (AHU), where the first tag indicates a type of cooling system used in AHUs. As a further example, the ontology 505 may include a second tag “chilled water cooling” associated with a cooling air unit.

The text classification component 140 may also determine equipment instance names that are unique identifiers composed of an equipment type and a suffix (e.g., AHU-1). An equipment instance name may be determined based on information extracted from the image data 122. An example is illustrated in FIG. 4C, where a portion of the image data 122 may include text “MTE-1” which results in the text classification component 140 identifying “MTE-1” as an equipment instance name corresponding to a piece of equipment included in a building. In some embodiments, individual pieces of equipment may be associated with unique equipment instance names for a given building (e.g., “AHU-1”, “AHU-2”, etc.). The ontology 505 may include the types of equipment relationships, and the instantiation of equipment relationships are based on equipment instance names. As a further example, using the ontology 505, the text classification component 140 may determine, the equipment relationship “AHU-1 is a parent of VAV-1”, and the equipment location “AHU-1 has location Rooftop.”

The text classification component 140 may be configured to perform a multi-class classification task. The text classification component 140 may employ one or more ML models 510 shown in FIG. 5. Example ML model(s) for multi-class text classification tasks are a character-level Recurrent Neural Network (RNN), Embeddings Bag+Linear Output, Long-Short Term Memory (LSTM) model, and Transformer-based Neural Network.

In some embodiments, the text classification component 140 may use an LSTM architecture 515, which may accept strings of variable length, and may learn from the structure of ordered word inputs. Certain data extracted from building engineering drawings (e.g., BACnet systems), can contain up to 70 words in a single sample, while other of the samples contain less than 20 words. In order to feed the words into the LSTM 515 embeddings layer, each unique word may be converted into a numeric token. The embeddings layer may be trained using words related to HVAC abbreviations and vocabulary specific to building engineering drawings.

In an example embodiment, the LSTM architecture 515 may include an embedding layer, LSTM layers and two distinct linear layers. The first linear layer may include, for example, 27 output nodes for each equipment class, and the second linear layer may include, for example, 198 nodes for each point class. For model parameters, the embeddings layer may have, for example, 50 dimensions, the LSTM 515 may have, for example, 30 hidden layers and a dropout pass, which randomly turns off, for example, 40% of the nodes in the hidden layers to prevent overfitting to the training data.

The text classification component 140 may additionally or alternatively include a ML model 520, which may be a deep multi-task learning model that can classify both the equipment and point type labels with a unified architecture. The ML model 520 may use a multi-task loss function, where the objective of the loss function is to minimize a weighted sum of the cross-entropy loss for both tasks. During training operations, learnable weights for the ML model 520 may be tuned with each training epoch with all other parameters in the model. An adaptive learning rate optimization method may also be implemented for the ML model 520 for updating the model weights for each training epoch. The ML model 520 may involve deep learning techniques, which are useful for highly varied data because of its ability for representation learning—with either supervised or unsupervised methods or combination of both, deep learning can be used to learn good feature representations for classification tasks. Deep learning is able to discover intermediate or abstract representations, which is carried out using unsupervised learning in a hierarchy fashion: one level at a time and higher-level features defined by lower-level features. A solution to address the data integration problem is to learn data representations from individual data sources using deep learning methods, and then to integrate the learned features at different levels. The system 100 may be configured to integrate data from less structured sources like engineering drawings and automatically learn abstract feature representations across tasks by utilizing a deep learning based multi-task learning system and achieving a high level of classification accuracy.

In some embodiments, the text classification component 140 may include one or more convolutional neural networks (CNNs) 525, which may learn a hierarchical feature representation by utilizing strategies like local receptive fields, shared weights (using the same weights to construct the feature maps at the same level significantly reduces the number of parameters), and subsampling (to further reduce the dimensionality). A filter bank of the CNN 525 can be trained with either supervised or unsupervised methods. A CNN is capable of learning good feature hierarchies automatically and providing some degree of translational and distortional invariances. Using the CNN 525, the text classification component 140 can utilize hierarchical feature representations across all tasks as well as develop task-specific convolutional decoding layers.

The text classification component 140 may involve feature-based multi-task learning using developed neural-network based deep learning models that can learn common feature-representations among different tasks. In order to configure the text classification component 140, label dependencies and task clustering may be considered and developed, and a measure of task relatedness across the four labels of point type, equipment type, equipment instance, and equipment relationship may be developed. The measure of task relatedness can determine ‘what to share’ and ‘when to share’ training data across tasks and can inform the overall neural network architecture where more closely aligned tasks share more convolutional layers. Both relatively deep and shallow architectures may be used. Deep learning has been shown to perform better on data from similar tasks, while relatively shallow models can perform better by more generalized learning from diverse areas. In addition to feature-based multi-task learning, the text classification component 140 may involve instance-based learning where useful data instances are identified in one task and knowledge between tasks is shared, such as the specific senor points which are used in equipment relationship classification.

The text classification component 140 may be configured using a bottom-up approach for building information modeling starting at the individual sensor level and building up to a complex data model that includes equipment functional relationships. Some embodiments of the text classification component 140 may perform classification sequentially, which may first involve determining a point label and an equipment label for the text data 132, then determining an equipment instance label, and then using that information to classify functional equipment relationships.

Some embodiments of the text classification component 140 may use the multi-task learning framework described above to consider the specific uncertainties of each labeling task in a unified loss function. The text classification component 140 may involve weighting or scaling task-specific loss functions across labels to optimize overall performance and achieve a high level of classification accuracy across all tasks.

Referring to FIG. 1, the text classification component 140 may output (step 4) one or more text-labels data 142, which may represent an association between the text data 132 and one or more of the point type label, equipment type label, equipment instance label and equipment relationship label. For example, the text-labels data 142a may include the text data 132a and a point type label identifier (e.g., a point type name, a numerical value associated with a point type, etc.).

The point type label describes what a sensor is measuring (e.g., Outdoor Air Temperature, Hot Water Return Temperature, Mixing Valve, etc.). The equipment type label describes what equipment the sensor is connected to (e.g., Air Handling Unit, Heat Exchanger, Variable Air Volume Box, etc.). In some examples, the text classification component 140 may be configured to identify a large number (e.g., between 100 and 1000) of unique point type labels.

The equipment instance labels are used to group raw collections of individual sensors, actuators and setpoints into the same equipment node. An example of the equipment instance label references the “1-10” in the text data “VAV 1-10” based on identifying “1-10” as an instance of the equipment “VAV.”

The processing performed by the system 100 may be used to develop an end-to-end platform for acquiring, normalizing, performing quality-assurance, and distributing actionable building data. Once a BACnet scan, streaming data and user uploaded engineering drawings are received, the system 100 can process the data, automatically classify the metadata, and store the results in a relational database.

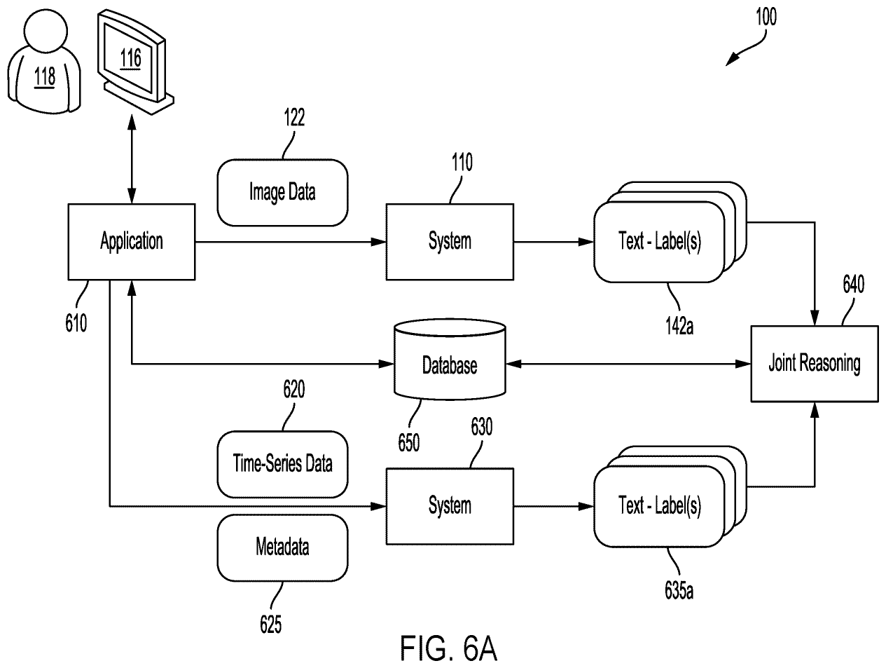

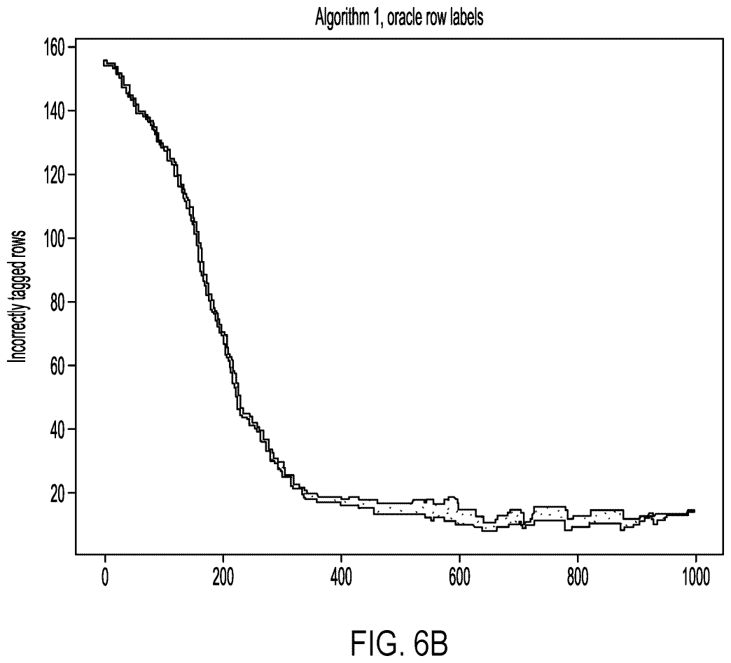

FIG. 6A shows further components of the system 100 that can be used to provide actionable building data for various tasks. The system 100 may include a platform that may include a full stack application (e.g., application 610) in a user-facing environment for acquiring, storing and distributing building data. The application 610 may use mechanisms (e.g., open source software) for acquiring and real-time streaming of building data. The application 610 may be configured to process and store streaming data in a time-series specific database (not shown). The application 610 may include a back-end rest API for serving data to a front-end GUI application, and a user-facing API for distributing building actionable data determined by the system 100.

The system 630 may receive and process time series data 620, which may include a series of data values taken/measured at different times for different points associated with equipment in a building. The system 630 may also receive metadata 625, which may include information about the equipment in the building, where such information may be represented as structured text, unstructured text, or in other forms. The user 118, via the application 610, may enable the system 630 to receive the time series data 620 and the metadata 625. In some embodiments, the user 118 may establish (using the application 610) a connection between the system 630 and a building control network of the building, so that the system 630 may receive the time-series data 620 and/or the metadata 625 from the building control network. In other embodiments, the user 118 may upload, provide as input, etc. the time-series data 620 and/or the metadata 625 to the application 610, which in turn may provide the data to the system 630.

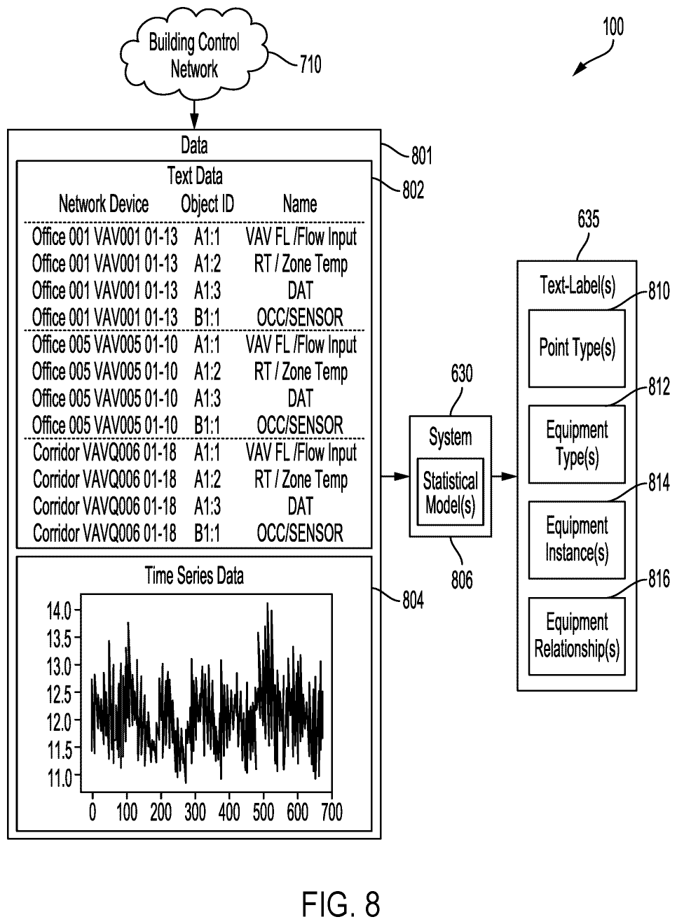

For building metadata classification, the metadata 625 and the time-series data 620 may be converted to flat files, which may be provided to a system 630 for processing (e.g., label classification). The system 630 may be configured to process data to determine text-labels data 635, which may be labels (e.g., point type label, equipment type label, equipment instance label, and equipment relationship label) associated with portions of the metadata 625. Further details of the system 630 are described below in relation to FIG. 8.

The image data 122 for the buildings is processed using the system 100 to extract the list of equipment instances from the mechanical schedules, that may be represented in the text-labels data 142. The classification results (the text-labels data 635) and list of equipment instances (the text-labels data 142) may be combined into a flat file, which may be presented to the user 118 (e.g., a mechanical engineer, a building engineer, etc.), via the application 610 at the device 116, who can perform quality assurance checks. For example, the user 118 may review labels with low predicted probability, and may provide inputs to make corrections as needed. The metadata profile, along with any correctional updates, for the building may then be saved in a database 650 (e.g., a relational database). The metadata profile may represent information extracted (using the system 100 described herein) from various data sources (described above) for a building. The metadata profile may be displayed to another user 118 (e.g., a building analyst, a building manager, etc.) via front-end GUI application at another device 116, so that the user can view and analyze building data, for example, to identify faults, identify trends, plan maintenance projects, tune equipment operations, analyze energy usage, etc.

The application 610 may include a user interface that enables a user (e.g., a building engineer) to correct any errors from the system 110 before the metadata profile is provided to end-users. An example correction to building metadata labels may be changing the equipment class from ‘Pump’ to ‘Fan’. The user interface can improve speed and reduce errors that arise from manual-editing. The corrections may be used as ground-truth labels that can be used in retraining and improving the system 110.

As shown in FIG. 6A, the system 100 may include a joint reasoning component 640 that may receive the text-labels 142, generated by the system 110, and the text-labels 635, generated by the system 630. As described herein, the text-labels 142 may be determined by processing building drawings included in the image data 122. As described herein, the text-labels 635 may be determined by processing sensor and equipment data obtained from a building control network and included in the metadata 625 and the time-series data 620. The joint reasoning component 640 may be configured to reconcile the results of the two systems 110, 630, such that the text-labels 142 may be updated based on the text-labels 635 to, for example, correct and mislabeling or prediction errors by the system 110. The joint reasoning component 640 may output updated/final text-labels for building data, which may be stored in the database 650. The updated/final text-labels may be presented via the application 610 in addition to or instead of the text-labels 142, 635.

The joint reasoning component 640 may employ one or more algorithms, rules, or other techniques. In an example embodiment, the joint reasoning component 640 may iteratively adjust the text-labels 142 until a condition (e.g., an equilibrium) is satisfied with respect to the text-labels 635.

Some embodiments involve a component (e.g., implementing custom software code) that facilitates the joint reasoning task of the joint reasoning component 640. The component may be configured to present the user 118 (e.g., an engineer of the system 100, a building engineer, a mechanical engineer, etc.) with text extracted from engineering drawings (e.g., the text data 132), and enables the user 118 to annotate them with the labels that the system 630 is configured to identify (e.g., equipment type, equipment instance, location, and point type). In some embodiments, the portion of the engineering drawing (e.g., the image regions 128) may also be presented. Such text and images may be presented via the application 610. In this manner, the system 100 may extract text and image portions from engineering drawings, and present them to a user with a goal of receiving labels for the text and images. The labels provided by the user 118 may be used as ground-truth labels, training data, etc. for the joint reasoning component 640, the text classification component 140, or other components of the system 100. In some embodiments, the user 118 is presented with a summary of the equipment and sensors described in the engineering drawings and extracted using one or more components of the system 100 (e.g., the image processing component 120, the text recognition component 130, etc.). In some cases, the user 118 may be presented with text or image portions that may have been segmented/detected incorrectly. The user 118 can provide inputs to illustrate the correct segments of the engineering drawing, and such inputs may be used to update/train the image processing component 120 and/or other components of the system 100.

In some embodiments, the inputs provided by the user 118 and labeling the text, the image portions and/or the summaries of the equipment and sensors, may be used to by the joint reasoning component 640 to iteratively update the models of the system 630 (e.g., statistical models 806 shown in FIG. 8). As part of updating the models, the joint reasoning component 640 may re-weight the output probabilities of the statistical models 806 until the outcomes more closely match the inputs provided by the user 118. On each iteration, the joint reasoning component 640 may determine the set of point and equipment types that are underrepresented in the predictions from the statistical models 806 and increases the probability associated with each of those point and equipment types across all rows of the text (see FIG. 6B). As part of updating the models, in some embodiments, the probabilities associated with underrepresented point and equipment types are changed, and overrepresented point and equipment types are not penalized more than point and equipment types which report identical instances as the component's output.

For example, if the model labels a given row as 60% likely to be equipment type A and 40% likely to be equipment type B, and the joint reasoning component 640 determines that equipment type B is underrepresented in the model's predictions, the weight associated with equipment type B will be increased across all rows, and the probabilities will be recalculated. The new prediction for that row may now be 59% likely to be equipment type A and 41% likely to be equipment type B. Following enough of these updates, equipment type B will cease to be underrepresented and a new set of equipment types will be adjusted, eventually leading to a near-equilibrium.

Rather than running iterations until the model predictions reach an equilibrium, in some embodiments, a stopping rule is defined based on how certain the accounting of the buildings based on the engineering drawings is. For point and equipment information derived from engineering drawings and that are evaluated by an expert user 118, this certainty may be assumed to be high, and consequently the re-weighting may run for many iterations. For engineering drawings that are automatically summarized (e.g., not evaluated by an expert user), the number of iterations may be determined by the inferred certainty of that summary.

Prior to the summary-based reweighting process, models weights may be pre-adjusted through a series of heuristics in some embodiments. For example, the format of the data being generated by the system 630 is compared against a dictionary containing possible formats for given point types. The weights of all point types that are incompatible with the generated data format are reduced, affecting downstream calculations of probability.

FIG. 6B shows a graph illustrating steps through the iterative re-weighting process of the joint reasoning component 640. Here, the correct label for each row is known, and at every iteration the number of rows that are incorrectly tagged (based on a mismatch between the top-probability guess for each row and the correct answer) is calculated. After a number of iterations, the predictions reach a relatively stable state and the reweighting process is stopped (if it was not previously stopped based on the stopping criteria).

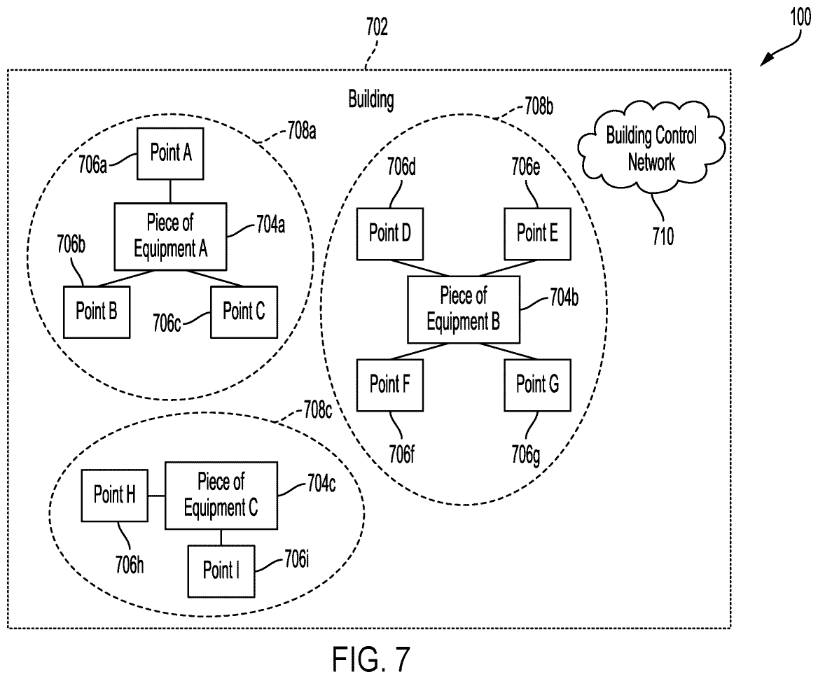

FIG. 7 is a conceptual diagram illustrating some example equipment included in a building 702. A building control network 710, controlling the building 702, may be used to obtain data for processing by the system 630 and/or the system 110. The image data 122 processed by the system 110 may represent, via engineering drawings, the conceptual information illustrated in FIG. 7.

As shown in FIG. 7, building 702 includes piece of equipment A 704a, piece of equipment B 704b, and piece of equipment C 704c that are part of one or more building systems (e.g., heating, ventilation, and air conditioning (HVAC), humidity control, lighting) of building 702. Examples of types of pieces of equipment include air handling units, variable-air-volume boxes, boilers, chillers, fans, filters, and thermostats. Although only three pieces of equipment are shown in FIG. 7, it should be appreciated that more or fewer pieces of equipment may be included as part of a building system.

One or more measurements points (also referred to herein as “points”) may be associated with individual pieces of equipment. For example, FIG. 7 shows piece of equipment A 704a associated with point A 706a, point B 706b, and point C 706c. As another example, piece of equipment B 704b is associated with point D 706d, point E 706e, point F 706f, and point G 706g. As yet another example, piece of equipment C 704c is associated with point H 706h and point I 706i. Examples of types of points include an air flow sensor, a temperature sensor, an actuator, a setpoint, an alarm, a motion detector.

A group of points associated with a particular piece of equipment may refer to an “equipment instance.” FIG. 7 shows equipment instances 708a, 708b, and 708c in the dashed circles and associated with piece of equipment A 704a, piece of equipment B 704b, and piece of equipment C 704c, respectively. Equipment instance 708a includes point A 706a, point B 706b, and point C 706C. Equipment instance 708b includes point D 706d, point E 706e, point F 706f, and point G 706g. Equipment instance 708c includes point H 706h and point I 706i. For example, piece of equipment A 704a may be a variable-air-volume box, point A 706a may be an air flow sensor, point B 706b may be a temperature sensor, and point C 706c may be a setpoint.

Building control network 710 associated with building 702 may provide communication services between control systems and devices of building 702, including piece of equipment A 704a, piece of equipment B 704b, and piece of equipment C 704c and point A 706a, point B 706b, point C 706c, point D 706d, point E 706e, point F 706f, point G 706g, point H 706h, and point I 706i. Building control network 710 may be configured to implement one or more communication protocols (e.g., BACnet, Modbus). Building control network 710 may provide the capability to control and monitor building automation process(es) of building 702. For example, building 702 may include a HVAC system, and building control network 710 may control of pieces of equipment of building 702 that provide heating, cooling, and ventilation for building 702. In addition, building control network 710 may receive data from motion detector(s) of building 702 which may be used to detect human presence and activity, which may be used in controlling the pieces of equipment of building 702 that provide heating, cooling, and ventilation for building 702.

FIG. 8 is a conceptual diagram illustrating further components of the system 100, which may include the system 630. The system 630 may process data 801 that may be obtained from measurement points (also referred to herein as “points”) in a building automation and control network for the building 702. As shown in FIG. 8, the data 801 may be obtained from the building control network 710 and may be processed using the system 630. The data 801 may include time-series data 804 including a series of data values at different times for different points associated with the equipment in the building 702. The data 801 may also or instead include text data 802, which may include structured data and/or unstructured data. For example, structured text data may be text values for different data fields in a relational database. Unstructured text data may be text values that lack an organized storage format. Example sources of unstructured text data are files, documents, websites, sensor data, etc. The format of the data outputted from points associated with a building may vary among different equipment suppliers, causing variation in the structured text fields and unstructured text descriptions used in the output data.

The system 630 may include one or more statistical models 806, and/or other components. The system 630 may be configured to identify label(s) for measurement point(s) and piece(s) of equipment located at the building 702 using one or more computational techniques. The system 630 may be implemented on any suitable computing device(s) (e.g., a single computing device, multiple computing device(s) co-located in a single physical location or located in multiple physical locations remote from one another, one or more computing devices part of a cloud computing system, etc.) as aspects of the technology described herein are not limited in this respect. In some embodiments, the system 630 may be implemented at a desktop computer, a laptop computer, or a mobile computing device. In some embodiments, the system 630 may be implemented within one or more computing devices that are part of a cloud computing environment.

In some embodiments, the system 630 may determine an operational relationship between two or more pieces of equipment using the techniques described herein. For example, an operational relationship between an air handling unit and a variable-air-volume box, where the air handling unit is downstream of the variable-air-volume box may be identified using the system 630. If either the air handling unit or the variable-air-volume box has reduced performance, then the air handling unit and/or the variable-air-volume box may be identified as being in need of service. In this manner, the text-labels data 635 determined using data 801 and the system 630 may then be used to identify piece(s) of equipment in need of service. Examples of failures that may require service include cooling or heating valve failure in an air handling unit, cooling coil in an air handling unit is fouled and cannot maintain specified heat transfer, supply air filter is dirty or blocked. In addition, the text-labels data 635 may then be used to identify piece(s) of equipment that are likely to fail or running inefficiently. As an example, a variable-air-volume box may be identified as being inoperative by determining an operational relationship between the variable-air-volume box and an air handling unit and detecting from measurements obtained from points associated with both the variable-air-volume box and the air handling unit that supply fan speed and discharge air flow associated with the air handling unit has increased and discharge air flow associated with the variable-air-volume box remains the same or similar. In some embodiments, information generated by the system 630 may be used in predicting when a piece of equipment is likely to need service in the future. In such embodiments, historical sensor data obtained by monitoring equipment in a building may be used in predicting future occurrences of faults and failures for pieces of equipment in the building.

In some embodiments, information generated by the system 630 may be used in monitoring CO₂ concentration in a building. The system 630 may be used in determining one or more of the points in the building 702 as being a CO₂ sensor. CO₂ measurements may be binned according as being a particular level, such as a low level, a medium level, and a high level, within a duration of time (e.g., 12 hours, 24 hours). Monitoring CO₂ concentration in a building may allow for detecting an error with another piece of equipment that may impact air quality in the building. For example, monitoring CO₂ concentration may include determining that the building has a high level of CO₂. which may indicate that an outdoor air damper is ineffective in letting in enough fresh air into the building.

In some embodiments, information generated by the system 630 may be used in detecting an error with an outdoor air sensor. The system 630 may be used in determining one or more of the points for a building as being an outdoor air sensor. Temperature measurements obtained from the outdoor air sensor may be compared to a third-party weather data to determine whether the outdoor air sensor is accurately measuring temperature. If temperature measurements obtained from the outdoor air sensor and the third-party weather data are not the same or similar, then further action may involve calibrating the outdoor air sensor or replacing the outdoor air sensor.

In some embodiments, information generated by the system 630 may be used in monitoring occupancy for a building, including occupancy for different rooms within the building. The system 630 may be used in determining one or more of the points for a building as being a motion sensor. Data from the motion sensor may be analyzed over time to monitor building occupancy. Labeling of specific points in the building may allow owners and operators of the building to track real-time capacity and location throughout the building. In some embodiments, tracking occupancy in a building may be used in operating devices (e.g., turnstiles) located at access points of the building and/or managing security personnel at access points.

In some embodiments, information generated by the system 630 may be used in monitoring indoor air quality. The system 630 may be used in determining one or more of the points for a building as being air flow sensors, humidity sensors, temperature sensors, and other HVAC sensors. Data from these sensors may be used in monitoring indoor air quality for the building (e.g., hospital, school, lab, office space). Air quality may include high CO₂ level and/or presence of bacteria, virus, mites, or fungi. Monitoring indoor air quality may include determining that indoor air quality is below a threshold level and notifying an owner or occupant of the building that the indoor air quality is poor.

In some embodiments, information generated by the system 630 may be used in predicting energy consumption for a building. Data from points in the building 702 may be used in determining prior energy consumption for the building, which may be used in predicting future energy consumption for the building. Predicting future energy consumption may involve identifying when to shift thermal loads for a HVAC system of the building. For example, generating ice during off-peak energy consumption hours that is used to cool the building during the hottest part of the day may reduce energy costs.

In some embodiments, information generated by the system 630 may be used in monitoring indoor air temperature. The system 630 may be used in determining one or more of the points for a building as being temperature sensors, other HVAC sensors, and outdoor temperature sensors. Data from these sensors may be used in monitoring indoor air temperature for the building, which can impact thermal comfort for the building's occupants. Monitoring indoor air temperature may include determining if the building or a room in the building is above a threshold temperature on a hot day or below a threshold temperature on a cold day and notifying an owner or occupant of the building a status of thermal conditions for the building.

In some embodiments, information generated by the system 630 may be used in adjusting temperature set points for the building. The system 630 may be used in determining one or more of the points for a building as being temperature set points. These temperature set points may be adjusted based on an indication identifying a change in energy rates and/or usage for a location of the building. For example, the temperature setpoints may be automatically raised when energy demand rates increase and/or the electric grid has a cap on the amount of energy a particular building can use. In some embodiments, the building may switch to on-site energy generation in response to an indication identifying a change in energy rates and/or usage. On-site energy generation may include one or more renewable energy sources (e.g., solar, wind) or a natural gas fired combined heat and power plant (CHP).

In some embodiments, information generated by the system 630 may be used in controlling energy load for a building. Controlling energy load for the building may involve adjusting energy load for the building during a duration of time having high energy usage for a location of the building (e.g., peak energy usage). Energy load may include energy usage from devices within a building (e.g., heating, cooling, lighting, electric vehicles) and energy resources (e.g., energy storage, energy generation assets). Controlling energy load for the building may allow building owners and operators to manage energy usage during peak electricity periods and maintain a desired performance of the building.

In some embodiments, information generated by the system 630 may be used to provide indoor navigation information. The system 630 may be used in labeling points for a building, and this information may be inputted to an augmented or virtual reality software platform, which may allow a person to navigate building floors and spaces. In some embodiments, information generated by the system 630 may be used to in providing real-time data to a technician relating to status of one or more pieces of equipment in the building. The technician may provide information to a person at the building to allow the person to perform a guided repair of the one or more pieces of equipment.

In some embodiments, information generated by the system 630 may be used to provide elevator position information. The system 630 may be used in determining one or more of the points for a building associated with an elevator of the building. Data from these points may be used in monitoring position of the elevator, and the elevator position information may be provided to a person (e.g., a tenant of the building). The elevator position information may include an indication that the elevator is delayed or is in need of service.

In some embodiments, information generated by the system 630 may be used to monitor water usage for a building. The system 630 may be used in determining one or more of the points for a building as being water flow sensors. Data from these points may be used in monitoring water usage for the building. Monitoring water usage for the building may include detecting a water leak for the building. Detecting a water leak may include detecting water usage occurring above a threshold value, and notifying a person (e.g., owner of the building, tenant of the building) of a possible water leakage. Monitoring water usage may be used by building owners and operators to monitor billing through the seasons or from particular tenants.

As shown in FIG. 8, data 801 obtained from the building control network 710, may include text data 802 and time series data 804. Data 801 may correspond to point(s) 706 associated with piece(s) of equipment 704 located in the building 702 controlled by the building control network 710. Data 801 may be provided as an input to the statistical model(s) 806 to obtain an output indicating text-labels data 635. Text-labels data 635 may include point type(s) 810, equipment type(s) 812, equipment instance(s) 814, and equipment relationship(s) 816. The point type(s) label 810 may include a sensor, an actuator, a setpoint, an alarm and the like. The equipment type(s) label 812 may include an air handling unit, a variable-air-volume box, a boiler, a chiller, a fan, a filter, a thermostat, and the like.

The system 630 may process the time series data 804 prior to providing to the statistical model(s) 806. Examples of processing performed by the system 630 of the time series data 804 include removing one or more outliers or adding one or more missing values where there is no data value for a particular point in time. Removing one or more outliers may involve removing one or more data points in a raw data trace that are either below or above a threshold value.

Some embodiments involve training the statistical model(s) 806 using training data corresponding to multiple point types and equipment types for different pieces of equipment. Training data may include data corresponding to at least 100 different point types, at least 200 different point types, or at least 300 different point types, in some embodiments. Training data may include data corresponding to at least 10 different equipment types, at least 20 different equipment types, or at least 25 different equipment types, in some embodiments.

The time series data 804 may be obtained for point(s) 706 associated with piece(s) of equipment 704. The time series data 804 may include individual data traces, corresponding to individual points.

The point type(s) label 810 for point(s) associated with piece(s) of equipment may be determined using time series data 804 and the statistical model(s) 806. Equipment type(s) 212 for point(s) associated with the piece(s) of equipment may be determined using the time series data 804 and the statistical models 806.

In some embodiments, the statistical model(s) 806 may include one or more neural networks. Determining point type(s) 810 may involve providing time series data 804 as an input to the one or more neural networks and obtaining an output indicating point type(s) 810 as an output. Similarly, determining equipment type(s) 812 may involve providing time series data 804 data as an input to the one or more neural networks and obtaining an output indicating equipment type(s) 812 as an output. In some embodiments, statistical model 806 may include a 1-dimensional convolutional neural network. The 1-dimensional convolutional neural network may extract patterns from time series data 804 and map those patterns to point type(s) 810 and equipment type(s) 812. In some embodiments, training the one or more neural networks may involve performing layer normalization. Since time series data 804 obtained from different points may vary in magnitude, layer normalization may allow for comparing data obtained from different with each other. Since time series data 804 obtained from different points may belong to different measurement types and/or have different units, which may vary by orders of magnitude, layer normalization may allow for comparing these data from diverse data sources. The layer normalization may allow for comparing different magnitudes observed in points between buildings as well as mixed data types and scales, which may vary depending on the type of measurement being obtained (e.g., parts-per-million (ppm) for CO₂ concentration, kWh for energy consumption).

Some embodiments involve performing a normalization process on time series data 804 to obtain normalized time series data. The normalization process may process time series data 804 such that the data values are within a particular data range. Determining point type(s) 810 may involve providing the normalized time series data as an input to statistical model 806 and obtaining an output indicating point type(s) 810 as an output. Similarly, determining equipment type(s) 812 may involve providing the normalized time series data as an input to statistical model 806 and obtaining an output indicating point type(s) 812 as an output.

In some embodiments, the statistical models 806 may include encoder(s) used to obtain feature(s) of time series data 804, and classifier(s) that use the feature(s) to identify point type(s) 810 and equipment type(s) 812 of the time series data. Examples of classifier(s) include, but are not limited to, a support vector machine classifier, a logistic regression classifier, a gradient boosted classifier, a decision tree classifier, a Bayesian classifier, a Bayesian network classifier, a random forest classifier, a k-nearest neighbors classifier, a neural network classifier, and an extremely randomized trees classifier.

The statistical model(s) 806 may output predictions indicating whether time series data 804 is categorized as being particular point types and/or equipment types. The statistical model(s) 806 may output predictions for multiple equipment types, including an air handling unit, a variable-air-volume box, a boiler, a chiller, a fan, a filter, a thermostat, etc. The predictions may include values corresponding to different point types and/or equipment types. Determining a point type for time series data 804 may involve selecting, based on the values corresponding to multiple point types, a point type for time series data 804. Determining an equipment type for time series data 804 may involve selecting, based on the values corresponding to multiple equipment types, an equipment type for time series data 804.

In some embodiments, the statistical model(s) 806may include one or more binary classifiers. A binary classifier may correspond to a particular label, such as a particular point type and/or equipment type. The binary classifier may output a prediction indicating whether the time series data is categorized as being a particular point type and/or equipment type. For example, the first point type may be a temperature sensor and the second point type may be a temperature set point. A first classifier may output a prediction indicating whether the time series data is categorized as being a temperature sensor, and a second classifier may output a prediction indicating whether the time series data is categorized as being a set point. Using the outputs from both the first classifier and the second classifier, the time series data may be categorized as being either the temperature sensor or the temperature set point.

Data feature(s) corresponding to the time series data 804 may include a mean value, a median value, a standard deviation value, a kurtosis value, a skewness value, a minimum value, a maximum value, a median absolute deviation value, a mean absolute deviation value, and an interquartile range value, an autocorrelation value for time series data 804. In some embodiments, data feature(s) may include a correlation value between data obtained from two different points. Time series data 804 may include time series data obtained from a first point and a second point and a correlation value between the time series data obtained from the first point and the second point. Data feature(s) may include the correlation value, which may be provided as an input to statistical model(s) 806 to determine point type(s) 810 and equipment type(s) 812. Some point types, such as temperature sensors, may correlate with outdoor temperature. In some embodiments, data feature(s) may include a correlation value between time series data 804 and outdoor temperature for a location of the building.

Some embodiments involve applying a multidimensional transformation process to time series data and then using the transformed data as an input to statistical model(s). The multidimensional transformation process may transform the time series data into a multidimensional array. The multidimensional array may provide certain benefits in representing patterns or correlations in the time series data, which may improve the ability of some statistical models to learn such patterns and correlations.

Some embodiments may involve processing the time series data 804 using multiple statistical models to obtain multiple outputs. The outputs may be provided as an input to a statistical model that determines relationships between the outputs to point type(s) and/or equipment type(s) for the time series data 804.

Some embodiments use text data 802 obtained from the building control network 710 to determine label(s) for points located at the building 702. The statistical model(s) 806 may include a model configured to process the text data 802, and output the text-labels data 635. The statistical model(s) 806 may include a clustering-based technique (e.g., Partitioning Around Medoids (PAM), k-means, and k-medoids).

Text data 802 may include structured data and unstructured data. Text data 802 may have a structured format, using rows and columns, and may be stored in a relational database.

In some embodiments, text data 802 and the statistical model(s) 806 may be used to determine equipment instance(s) 814 for the points 810 corresponding to text data 802. For example, a row in text data 802 may correspond to a particular point in a building controlled by a building control network and some or all or the text data in the row may be provided as input to the statistical model(s) 806 to determine an equipment instance for the row. A group of points having the same equipment instance may identify those points as being associated with a particular piece/instance of equipment. An equipment instance for each of these points may be identified as being associated with the same piece of equipment.

As the row numbers of text data 802 may provide information about equipment instance, some embodiments may involve providing information identifying row numbers for text data 802 as an input to the statistical model(s) 806 to obtain an output indicating equipment instance(s) 814.

In some embodiments, the statistical model(s) 806 may include an edge detection process for detecting “edges” between groups of points in the text data. The edge detection process may involve detecting groups of consecutive rows, in the text data 802, one or more “edges” may be detected between one of these groups and neighboring rows in the text data based on the edit difference between each row. In some embodiments, the edge detection process may include comparing one row to another row in the text data to determine a difference between the rows and comparing the difference to a detection threshold to determine whether an edge exists between the two rows. In validation experiments the accuracy of this technique can be measured by the cluster purity against ground-truth equipment instance labels.

In some embodiments, a group of points corresponding to an equipment instance may include points having different point types. The different point types may include two or more of: a sensor, an actuator, a setpoint, and an alarm. For example, an equipment instance for a variable-air-volume box may include a flow input sensor, a discharge air temperature sensor, and a temperature setpoint. As another example, an equipment instance for an air-handling unit may include an outdoor air sensor, a heating coil temperature sensor, a cooling coil temperature sensor, and a supply air temperature sensor. As yet another example, an equipment instance for a pump may include an on/off command controller, a speed sensor, and a flow sensor.

An equipment instance 814 may include any suitable number of points associated with a particular piece of equipment. In some embodiments, an equipment instance may include at least 1 point, at least 3 points, at least 5 points, at least 7 points, at least 10 points, or at least 15 points. In some embodiments, an equipment instance may include 1-5 points, 3-10 points, 3-15 points, or 3-50 points.

According to some embodiments, the statistical model(s) 806 may include a clustering-based classifier. In some embodiments, the statistical model(s) 806 may include a hierarchical classifier.

Some embodiments involve using a hierarchical classifier in determining equipment type(s) 812 using text data 802. For example, the statistical model(s) 806 may include in the first level a first classifier for fans, a second classifier for meters, a third classifier for chillers, and a fourth classifier for pumps. In the second level, the statistical model(s) 806 may include a first set of classifiers that receive an output from the first classifier, a second set of classifiers that receive an output from the second classifier, a third set of classifiers that receive an output from the third classifier, and a fourth set of classifiers that receive an output from the fourth classifier. The first set of classifiers may include a classifier for each of supply fan, exhaust fan, return fan, and relief fan. The second set of classifiers may include a classifier for each of electric meter, water meter, steam meter, and gas meter. The third set of classifiers may include a classifier for each of absorption chiller, centrifugal chiller, reciprocal chiller, and screw chiller. The fourth set of classifiers may include a classifier for each of chilled water pump, circulation pump, domestic water pump, dual temperature water pump, glycol pump, hot water pump, and condenser water pump.

The outputs from classifiers in the second level may be used in determining an equipment type(s) 812 for text data 802. In some embodiments, an output from a classifier in the second level may include one or more values indicating probability that text data 802 is likely to be the specific class type associated with the classifier. Determining equipment type(s) 812 may involve selecting a specific class type from among multiple specific class types based on the values associated with the outputs from classifiers for the multiple specific class types. In some embodiments, selecting the specific class type for text data 802 may involve selecting the specific class type having the highest probability among the multiple specific class types.

Some embodiments may involve extracting text values corresponding to one or more attributes of text data 802 and using the extracted text as an input to the statistical model(s) 806. In such embodiments, extracting text values from the one or more attributes for a point may involve removing punctuation in text values to generate filtered text, and using the filtered text as an input to statistical model(s) 806. Removing punctuation to generate filtered text may involve removing spaces, periods, hyphens, underscores, colons, semi-colons, slashes, or any other types of punctuation present in text data 802.

In some embodiments, extracting text from text data 802 may include extracting one or more acronyms from text values for one or more attributes of text data 802. A natural language dictionary relating common equipment specific acronyms may be used in extracting the one or more acronyms. Examples of equipment specific acronyms include “vav”, “fcu”, and “rtu” for the terms “variable-air volume”, “fan coil unit”, and “roof-top unit”, respectively.

In some embodiments, extracting text from text data 802 may include extracting a numeric suffix for data corresponding to point(s) and providing the numeric suffix as an input to statistical model(s) 806 in determining equipment instances for the point(s). Extracting the numeric suffix may involve using a regex function. In some instances, the numeric suffix may occur in text data 802 after a hyphen (“-”). Equipment instance names may also be generated for individual points using a multi-stage deep learning model. First, a classification algorithm determines if the metadata associated with an individual point is likely to contain sufficient information to recover an instance. Equipment instance names may then be generated from points with sufficiently descriptive metadata using a summarization model.

Some embodiments involve using a natural language dictionary to modify text values corresponding to attributes of the text data to generate modified text values and providing the modified text values as input to statistical model(s) 806. The natural language dictionary may relate terms for different types of equipment to shorthand versions (e.g., acronyms) of the terms. In some embodiments, the natural language dictionary may also include common terms to use when a group of terms are related in having the same or similar meaning. Modifying the text values may include replacing a term in the text values with a common term based on the natural language dictionary. For example, the acronyms “temp stpt” and “tmp spt” may both refer to a “temperature setpoint.” The natural language dictionary may be used to replace instances of “temp stpt” and “tmp spt” in text data to “temperature setpoint.” As another example, the acronyms “oad” and “oadmpr” may both refer to an “outside air damper.” The natural language dictionary may be used to replace instances of “oad” and “oadmpr” in text data to “outside air damper.”

In some embodiments, feature(s) of the natural language dictionary may be used in training a statistical model described herein. Such embodiments may involve determining the feature(s) of the terms included in the natural language dictionary and using the feature(s) in training the statistical model. In some embodiments, determining the feature(s) of the terms involves determining one or more term frequency-inverse document frequency (TF-IDF) values associated with individual terms in the natural language dictionary.

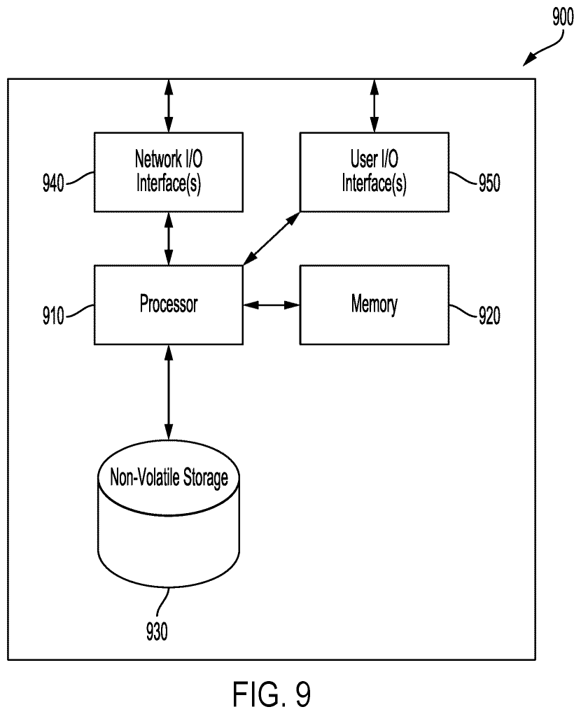

An illustrative implementation of a computer device/system 900 that may be used in connection with any of the embodiments of the technology described herein is shown in FIG. 9. The computer system 900 includes one or more processors 910 and one or more articles of manufacture that comprise non-transitory computer-readable storage media (e.g., memory 920 and one or more non-volatile storage media 930). The processor 910 may control writing data to and reading data from the memory 920 and the non-volatile storage device 930 in any suitable manner, as the aspects of the technology described herein are not limited in this respect. To perform any of the functionality described herein, the processor 910 may execute one or more processor-executable instructions stored in one or more non-transitory computer-readable storage media (e.g., the memory 920), which may serve as non-transitory computer-readable storage media storing processor-executable instructions for execution by the processor 910.

Computing device 900 may also include a network input/output (I/O) interface 940 via which the computing device may communicate with other computing devices (e.g., over a network), and may also include one or more user I/O interfaces 950, via which the computing device may provide output to and receive input from a user. The user I/O interfaces may include devices such as a keyboard, a mouse, a microphone, a display device (e.g., a monitor or touch screen), speakers, a camera, and/or various other types of I/O devices.

The embodiments described herein can be implemented in any of numerous ways. For example, the embodiments may be implemented using hardware, software or a combination thereof. When implemented in software, the software code can be executed on any suitable processor (e.g., a microprocessor) or collection of processors, whether provided in a single computing device or distributed among multiple computing devices. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of the embodiments described herein comprises at least one computer-readable storage medium (e.g., RAM, ROM, EEPROM, flash memory or other memory technology, CD-ROM, digital versatile disks (DVD) or other optical disk storage, magnetic cassettes, magnetic tape, magnetic disk storage or other magnetic storage devices, or other tangible, non-transitory computer-readable storage medium) encoded with a computer program (i.e., a plurality of executable instructions) that, when executed on one or more processors, performs the above-discussed functions of one or more embodiments. The computer-readable medium may be transportable such that the program stored thereon can be loaded onto any computing device to implement aspects of the techniques discussed herein. In addition, it should be appreciated that the reference to a computer program which, when executed, performs any of the above-discussed functions, is not limited to an application program running on a host computer. Rather, the terms computer program and software are used herein in a generic sense to reference any type of computer code (e.g., application software, firmware, microcode, or any other form of computer instruction) that can be employed to program one or more processors to implement aspects of the techniques discussed herein.

The terms “program” or “software” are used herein in a generic sense to refer to any type of computer code or set of processor-executable instructions that can be employed to program a computer or other processor to implement various aspects of embodiments as discussed above. Additionally, it should be appreciated that according to one aspect, one or more computer programs that when executed perform methods of the disclosure provided herein need not reside on a single computer or processor, but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in one or more non-transitory computer-readable storage media in any suitable form. For simplicity of illustration, data structures may be shown to have fields that are related through location in the data structure. Such relationships may likewise be achieved by assigning storage for the fields with locations in a non-transitory computer-readable medium that convey relationships between the fields. However, any suitable mechanism may be used to establish relationships among information in fields of a data structure, including through the use of pointers, tags or other mechanisms that establish relationships among data elements.

Also, various inventive concepts may be embodied as one or more processes, of which examples have been provided. The acts performed as part of each process may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, and/or ordinary meanings of the defined terms.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

Use of ordinal terms such as “first,” “second,” “third,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term).

The phraseology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the techniques described herein in detail, various modifications, and improvements will readily occur to those skilled in the art. Such modifications and improvements are intended to be within the spirit and scope of the disclosure. Accordingly, the foregoing description is by way of example only, and is not intended as limiting. The techniques are limited only as defined by the following claims and the equivalents thereto.

1. A computer-implemented method, the method comprising:
receiving image data representing at least a portion of an engineering drawing for a building, the building including equipment;
processing, using a first machine learning (ML) model, the image data to identify a first portion of the image data corresponding to a first region from a set of regions, wherein each region in the set of regions relates to a type of information included in the engineering drawing;
processing the first portion of the image data to recognize first text data;
determining, using at least a second ML model, that the first text data corresponds to a first equipment type from a set of equipment types, wherein the set of equipment types relate to the equipment included in the building, wherein the second ML model is configured to classify text as corresponding to one of the set of equipment types;
determining, using the first equipment type and an ontology representing relationships between equipment types and equipment attributes, a first equipment name corresponding to the first text data; and
presenting, via a user interface, first data indicative of the first equipment name along with a representation of the first portion of the image data and the first text data.

2. The method of claim 1, wherein processing the first portion of the image data comprises:
processing, using a third ML model configured to identify portions of an image including text, the first portion of the image data to identify a second portion of the first portion of the image data that includes text; and
processing, using a fourth ML model configured to transcribe text included in an image, the second portion of the first portion of the image data to determine the first text data.

3. The method of claim 2 or any other preceding claim, further comprising:
determining, using the at least second ML model, that the first text data corresponds to a first point type from a set of point types, wherein the set of point types relate to measurements available with respect to the equipment included in the building.

4. The method of claim 3 or any other preceding claim, further comprising:
determining, using the at least second ML model, that the first text data corresponds to a first equipment instance of the first equipment type; and
determining a first equipment instance identifier for the first equipment instance.

5. The method of claim 4 or any other preceding claim, further comprising:
determining, using the at least second ML model, that the first text data corresponds to a location, within the building, for an equipment instance from the equipment included in the building.

6. The method of claim 5 or any other preceding claim, further comprising:
selecting a text recognition technique, from a set of text recognition techniques, corresponding to the first region, the text recognition technique being configured to process the type of information included in the first region; and
determining, using the selected text recognition technique, the first text data from the first portion of the image data.

7. The method of claim 6 or any other preceding claim, further comprising:
receiving, via the user interface, input data indicating that the first portion of the image data corresponds to a second equipment type different than the first equipment type; and
based on the second equipment type being different than the first equipment type, updating the second ML model.

8. The method of claim 7 or any other preceding claim, wherein the set of regions include information blocks, diagrams, tables, connected text, HVAC layout, floor plans without HVAC layout, and scale.

9. The method of claim 8 or any other preceding claim, further comprising:
determining a second region, from the set of regions, corresponding to a second portion of the image data;
processing the second portion of the image data to recognize second text data;
determining, using at least the second ML model and the second text data, at least a second equipment type from the set of equipment types represented in the second portion of the image data; and
presenting, via the user interface, second data indicative of the second equipment type along with a representation of the second portion of the image data.

10. The method of claim 9 or any other preceding claim, further comprising:
receiving building data from a building control network for the building, wherein the building data includes second text data;
processing, using a statistical model, the second text data to determine a second equipment type corresponding to the second text data and a probability weight; and
based on the second ML model determining that the first text data corresponds to the first equipment type, updating the probability weight and the statistical model to cause the statistical model to predict the first equipment type instead of the second equipment type.

11. A system comprising:
at least one processor; and
at least one non-transitory computer-readable storage medium storing processor-executable instructions that, when executed by the at least one processor, cause the at least one processor to:
receive image data representing at least a portion of an engineering drawing for a building, the building including equipment;
process, using a first machine learning (ML) model, the image data to identify a first portion of the image data corresponding to a first region from a set of regions, wherein each region in the set of regions relates to a type of information included in the engineering drawing;
process the first portion of the image data to recognize first text data;
determine, using at least a second ML model, that the first text data corresponds to a first equipment type from a set of equipment types, wherein the set of equipment types relate to the equipment included in the building, wherein the second ML model is configured to classify text as corresponding to one of the set of equipment types;
determine, using the first equipment type and an ontology representing relationships between equipment types and equipment attributes, a first equipment name corresponding to the first text data; and
present, via a user interface, first data indicative of the first equipment name along with a representation of the first portion of the image data and the first text data.

12. The system of claim 11, wherein the at least one non-transitory computer-readable storage medium stores further processor-executable instructions that, when executed by the at least one processor, cause the at least one processor to:
process, using a third ML model configured to identify portions of an image including text, the first portion of the image data to identify a second portion of the first portion of the image data that includes text; and
process, using a fourth ML model configured to transcribe text included in an image, the second portion of the first portion of the image data to determine the first text data.

13. The system of claim 12 or any other preceding claim, wherein the at least one non-transitory computer-readable storage medium stores further processor-executable instructions that, when executed by the at least one processor, cause the at least one processor to:
determine, using the at least second ML model, that the first text data corresponds to a first point type from a set of point types, wherein the set of point types relate to measurements available with respect to the equipment included in the building.

14. The system of claim 13 or any other preceding claim, wherein the at least one non-transitory computer-readable storage medium stores further processor-executable instructions that, when executed by the at least one processor, cause the at least one processor to:
determine, using the at least second ML model, that the first text data corresponds to a first equipment instance of the first equipment type; and
determine a first equipment instance identifier for the first equipment instance.

15. The system of claim 14 or any other preceding claim, wherein the at least one non-transitory computer-readable storage medium stores further processor-executable instructions that, when executed by the at least one processor, cause the at least one processor to:
determine, using the at least second ML model, that the first text data corresponds to a location, within the building, for an equipment instance from the equipment included in the building.

16. The system of claim 15 or any other preceding claim, wherein the at least one non-transitory computer-readable storage medium stores further processor-executable instructions that, when executed by the at least one processor, cause the at least one processor to:
select a text recognition technique, from a set of text recognition techniques, corresponding to the first region, the text recognition technique being configured to process the type of information included in the first region; and
determine, using the selected text recognition technique, the first text data from the first portion of the image data.

17. The system of claim 16 or any other preceding claim, wherein the at least one non-transitory computer-readable storage medium stores further processor-executable instructions that, when executed by the at least one processor, cause the at least one processor to:
receive, via the user interface, input data indicating that the first portion of the image data corresponds to a second equipment type different than the first equipment type; and
based on the second equipment type being different than the first equipment type, update the second ML model.

18. The system of claim 17 or any other preceding claim, wherein the set of regions include information blocks, diagrams, tables, connected text, HVAC layout, floor plans without HVAC layout, and scale.

19. The system of claim 18 or any other preceding claim, wherein the at least one non-transitory computer-readable storage medium stores further processor-executable instructions that, when executed by the at least one processor, cause the at least one processor to:
determine a second region, from the set of regions, corresponding to a second portion of the image data;
process the second portion of the image data to recognize second text data;
determine, using at least the second ML model and the second text data, at least a second equipment type from the set of equipment types represented in the second portion of the image data; and
present, via the user interface, second data indicative of the second equipment type along with a representation of the second portion of the image data.

20. At least one non-transitory computer-readable storage medium storing processor-executable instructions that, when executed by at least one processor, cause the at least one processor to perform a method, the method comprising:
receiving image data representing at least a portion of an engineering drawing for a building, the building including equipment;
processing, using a first machine learning (ML) model, the image data to identify a first portion of the image data corresponding to a first region from a set of regions, wherein each region in the set of regions relates to a type of information included in the engineering drawing;
processing the first portion of the image data to recognize first text data;
determining, using at least a second ML model, that the first text data corresponds to a first equipment type from a set of equipment types, wherein the set of equipment types relate to the equipment included in the building, wherein the second ML model is configured to classify text as corresponding to one of the set of equipment types;
determining, using the first equipment type and an ontology representing relationships between equipment types and equipment attributes, a first equipment name corresponding to the first text data; and
presenting, via a user interface, first data indicative of the first equipment name along with a representation of the first portion of the image data and the first text data.
